(19) United States
(12) Patent Application Publication
(10) Pub. No.: US 2026/0074154 A1
(43) Pub. Date: Mar. 12, 2026

(54) Single Process Chamber for Dielectric Material Etching Using a Capacitively Coupled Plasma and Radical-Based Highly Selective Etching

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/882,769

(22) Filed: Sep. 12, 2024

(51) Int. Cl. H01J 37/32; H01L 21/311

(52) U.S. Cl. CPC H01J 37/32422; H01J 37/32091; H01J 37/321; H01J 37/32899; H01J 2237/334; H10P 50/283

(57) ABSTRACT

Disclosed is an advanced plasma process chamber for semiconductor fabrication, capable of performing both dielectric material etching with a capacitively coupled plasma (CCP) reactor and radical-based highly selective etching (HSE) within a single chamber. In some embodiments, a radical-based deposition step is also applied to enhance etching performance. The chamber features a novel grounded ion filter (GIF) designed for precise ion and neutral particle control, enabling efficient and high-precision etching processes essential for the fabrication of complex semiconductor devices.

### FIELD OF INVENTION

This invention pertains to semiconductor manufacturing, specifically focusing on advancements in plasma process chambers. It introduces novel designs and operational methods for conducting both dielectric etching using a capacitively coupled plasma (CCP) reactor and radical-based highly selective etching (HSE) within a radical reactor, both integrated into a single process chamber.

### BACKGROUND

The semiconductor manufacturing industry continually seeks advancements in fabrication technologies to meet the growing demands for smaller, more efficient, and more complex semiconductor devices. A critical aspect of semiconductor fabrication is plasma processing, which includes etching and deposition processes essential for creating patterns and structures on semiconductor wafers.

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion—and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{υ {E}_{i} {J}_{i}}{1 + ( υ {E}_{i} {J}_{i} ) / ( {υ}_{n} {sJ}_{n} )} , \qquad [ 1 ]$$

where v represents the volume removed per unit bombardment energy for a saturated surface (cm³/eV), Eᵢ the ion energy (eV), Jᵢ the ion flux to the surface (cm²/s), vₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of Inductive Coupled Plasma (ICP) or Transformer Coupled Plasma (TCP). Additionally, gas injection techniques have improved, incorporating multiple injection points to ensure a uniform plasma within the vacuum reactor, as described in U.S. Pat. No. 8,231,799 to Bera et al. and 10,825,659 to Treadwell. Further enhancements include optimizing the electrostatic chuck (ESC) to feature multiple zones with independently adjustable temperatures (U.S. Pat. No. 9,713,200 to Pease and 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for Critical Dimension (CD), loading, and profile remains a significant challenge, often entailing considerable expense.

Atomic layer etching (ALE) has been developed to address some limitations of RIE. ALE evolved from RIE technology but with less stringent requirements for achieving uniformity on a 300 mm wafer. While ALE can significantly improve etching performance in many applications, its effectiveness in extreme HAR structures, such as channel holes used in 3D NAND, is still under evaluation. Applications like channel hole etching, involving a stack of silicon oxide and silicon nitride, require the high ion energy provided by dielectric etching in a CCP reactor.

Conventional plasma processing techniques often involve multiple chambers or stations to perform various steps, such as etching, deposition, and cleaning. This multi-chamber approach can be inefficient, leading to longer fabrication times and higher costs. For example, a dielectric etching process may be followed by a radical-based HSE process, conventionally conducted in separate chambers. Dielectric material etching in a CCP reactor is anisotropic, removing material directionally, while radical-based HSE removes material isotropically. In certain cases, post-dielectric etching surfaces are sensitive to air exposure, which can lead to oxidation and defects. For example, when fluorine (F) is used in dielectric etching, air exposure can cause defects due to condensation. Integrating both the dielectric material etching and HSE processes within a single chamber could significantly reduce cycle time and improve process performance.

Furthermore, developing HAR structures and removing etch stop layers with precision presents substantial challenges, particularly in preserving the integrity of fine features and preventing damage to underlying layers.

Recent innovations have focused on improving plasma process chambers to address these challenges. However, there is still a need for a more integrated and efficient plasma processing system capable of handling multiple steps within a single chamber without compromising precision and quality. This need is especially critical in the context of advanced semiconductor devices, where the accuracy and quality of plasma processing directly affect the performance and reliability of the final product.

### SUMMARY

The present patent application discloses an innovative semiconductor processing system, focusing on an advanced plasma process chamber designed to significantly improve semiconductor fabrication techniques.

In some embodiments, the plasma process chamber is divided into an upper and lower chamber by a grounded ion filter (GIF). The GIF plays a critical role in controlling the flow of ions and neutrals during plasma processing, ensuring high precision in the etching process. The chamber also includes a window, a plasma source, an RF generator, and a first and a second gas distribution units that work together to facilitate efficient plasma processing.

In certain configurations, the GIF is described in detail, highlighting its ability to selectively allow neutrals to pass while blocking ions. The GIF may feature openings with specific dimensions and aspect ratios, and it can be constructed from materials such as aluminum or silicon, with anodization options to enhance erosion resistance.

The invention further explores various methods for introducing gases into the lower chamber, demonstrating the system's flexibility. These methods include diffusion through the GIF, direct introduction via internal gas distribution units, and configurations where the GIF functions as a showerhead.

The application also presents exemplary process sequences for dielectric material etching and radical-based HSE, showcasing the chamber's capability to handle complex etching tasks. These sequences include removing etch stop layers and protecting the sidewalls of high aspect ratio (HAR) structures, which streamline the semiconductor fabrication process.

In various operational modes, the lower chamber can be configured as a capacitively coupled plasma (CCP) reactor for dielectric material etching or as a radical reactor for radical-based HSE. Additionally, in some implementations, the lower chamber can be used for radical-based deposition, enhancing etching performance by protecting the sidewalls of structures during dielectric etching.

Overall, this patent application introduces a comprehensive solution for plasma processing in semiconductor manufacturing. The proposed system and methods, as detailed in different embodiments, offer significant improvements in efficiency, precision, and adaptability, potentially leading to the production of higher-quality, more reliable semiconductor devices.

### BRIEF DESCRIPTIONS OF THE DRAWINGS

To provide enhanced clarity, the following description references the accompanying drawings:

FIG. 1A illustrates an exemplary plasma process chamber of a semiconductor process system, partitioned into an upper and lower chamber by a GIF.

FIG. 1B presents a top view of the GIF, highlighting its design and structure.

FIG. 1C provides a detailed view of an exemplary design for the GIF, showcasing its specific features.

FIG. 2 depicts various alternative embodiments and designs of the GIF, demonstrating its versatility.

FIG. 3A illustrates two exemplary applications of the plasma process chamber in semiconductor processing.

FIG. 3B highlights the functions of the upper and lower chambers during dielectric material etching, radical-based etching, and radical-based deposition steps, respectively.

FIG. 4A shows a first implementation for introducing gas/precursor into the lower chamber.

FIG. 4B depicts a second implementation for gas/precursor introduction into the lower chamber through a version of the second gas/precursor distribution unit.

FIG. 4C presents a third implementation for gas/precursor introduction into the lower chamber through another version of the second gas/precursor distribution unit.

FIG. 4D showcases a fourth implementation for gas/precursor introduction into the lower chamber, utilizing yet another variation of the second gas/precursor distribution unit.

FIG. 5A illustrates a schematic flow of an integrated dielectric material etching and radical-based HSE process.

FIG. 5B provides a step-by-step flowchart, detailing the operations of the process system for etching a dielectric material layer, including a radical-based HSE step and optionally a radical-based deposition steps.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

### Terms Used in this Disclosure are Defined as Follows

Aspect Ratio: The ratio of the height to the width of a feature on a semiconductor wafer, critical in defining the geometry and performance of microstructures.

Bias Unit: A component that generates plasma or applies a controlled voltage to accelerate ions towards the wafer held by an electrostatic chuck (ESC), creating an electric field that enhances ion bombardment. This is essential for controlling ion energy and directionality in etching processes. In a CCP reactor, the bias unit can also be used to generate a plasma in the reactor.

Chamber: An enclosed environment within process equipment where semiconductor manufacturing processes, such as etching or deposition, occur.

Chuck: A component that holds and secures the wafer in place during semiconductor manufacturing processes.

Electrostatic Chuck (ESC): A type of chuck using electrostatic forces to secure the wafer during semiconductor processes, ensuring uniform clamping and stability.

Gas/Precursor Distribution Unit: A component designed to introduce and distribute gases or precursors across a substrate in a vacuum chamber. It may include an injector placed centrally or at specific angles, or a showerhead with a perforated plate to disperse gases. Side injection mechanisms promote lateral flow.

Gas/Precursor Source: The origin or supply point of process gases or precursors, typically connected to a centralized gas distribution system, ensuring proper gas composition and flow conditions in the process chamber. For precursors, vaporization units are commonly employed.

Grounded Ion Filter (GIF): A conductive plate dividing a vacuum chamber into upper and lower chambers. It allows neutrals to pass while blocking ions. The GIF includes openings designed for blocking the ions.

High Aspect Ratio (HAR): Features with a significantly greater height than width, posing challenges in maintaining uniformity and precision during manufacturing.

Highly Selective Etching (HSE): A radical-based etching process utilizing reactive radicals generated in plasma to selectively remove material layers with minimal impact on underlying or adjacent layers.

Lower Chamber: The lower section of a vacuum chamber, functioning as a CCP reactor during the sputtering step of ALE and as a radical reactor during radical-based HSE.

Plasma Enhanced ALE (or ALE): An atomic-level etching process that removes material layer by layer, offering precise control over etch depth and profile. It involves surface modification followed by physical ion bombardment to ensure high selectivity and precision.

Plasma Process Chamber: A vacuum chamber specifically designed for plasma-based processes, such as etching and deposition, where plasma activates chemical reactions or removes material from the wafer surface.

Plasma Source: A device that generates plasma for semiconductor processes, including inductively coupled plasma (ICP), transformer coupled plasma (TCP), and capacitively coupled plasma (CCP).

Process System: The equipment and machinery integrated for performing various semiconductor processes such as deposition, etching, or cleaning.

Reactive Ion Etching (RIE): A plasma-based etching technique where both ion bombardment and chemical reactions synergistically remove material from a substrate, offering precise control over etching.

Resonator: A device designed to resonate at a specific frequency, commonly used for RF impedance matching in circuits.

RF Power Generator: A device that produces radio frequency power for energizing plasma in processes like etching or deposition.

Sheath: The boundary layer between plasma and a surface, controlling the energy and flux of ions and electrons reaching the surface, critical for etching and deposition.

Substrate: The base material, typically a silicon wafer, upon which semiconductor devices are fabricated.

System Controller: The central unit responsible for managing and controlling the various operations and parameters of semiconductor manufacturing systems.

Transmission Line (RF): A specialized conductor designed to carry radio frequency signals with minimal loss, used to efficiently transfer RF power from the generator to the plasma source in semiconductor processes.

Upper Chamber: The upper section of a vacuum chamber, operating as an ICP reactor during ALE surface modification and radical-based HSE process.

Vacuum Chamber: An enclosed environment where air and gases are removed to create a low-pressure atmosphere, used in processes requiring precise atmospheric control.

Window: A non-conductive, transparent or semi-transparent barrier in a vacuum chamber that allows electromagnetic waves to pass through for plasma generation without exposing external components.

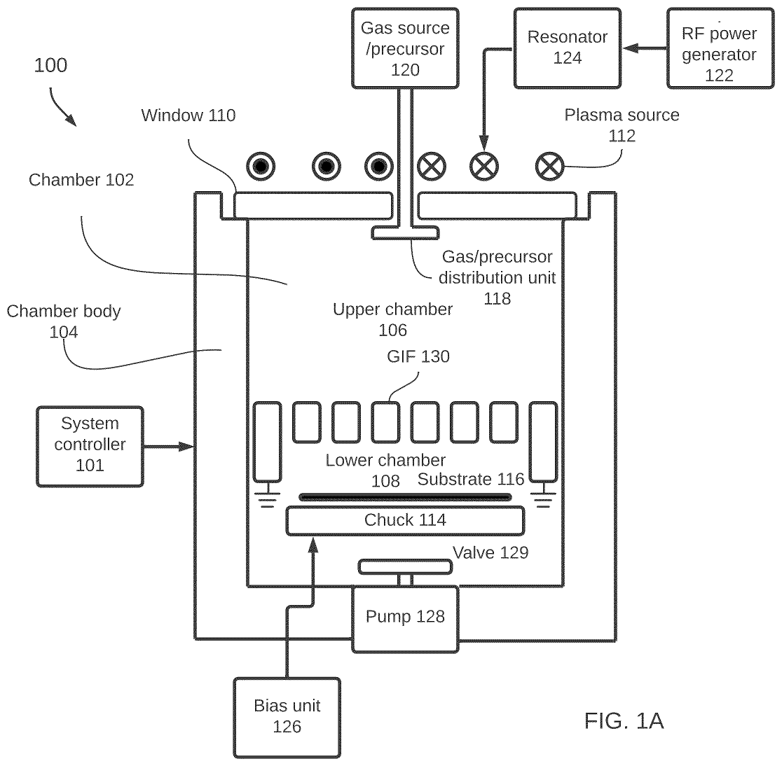

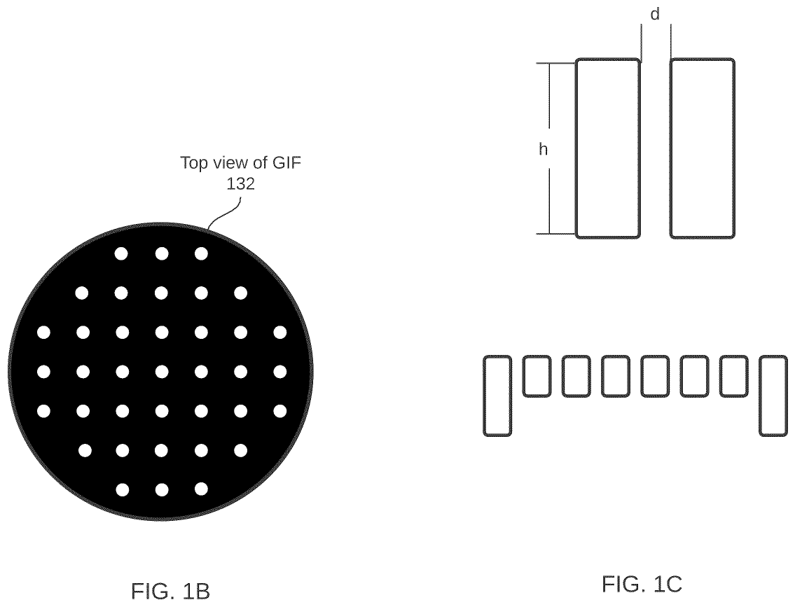

FIG. 1A illustrates an exemplary process system, designated as 100, which integrates a plasma process chamber (102). The operations within this chamber are controlled by a system controller (101). The chamber (102) is enclosed by a chamber body (104), creating a vacuum environment essential for plasma processing. A window (110) at the top of the chamber, made from quartz or ceramics in various embodiments, ensures a hermetic seal.

Above the window (110), a plasma source (112) is depicted, featuring a three-turn coil. However, this coil design can vary, with options including different numbers of turns or multiple coils, depending on specific operational requirements. Additionally, configurations such as cylindrical or conical coils may be used, as illustrated by the flat coil in FIG. 1A.

The plasma source (112) connects to an RF power generator (122) via a resonator (124). The RF power generator (122) is capable of producing RF power at multiple frequencies, including but not limited to 100 kHz, 400 kHz, 2 MHz, 13.56 MHz, and 60 MHz. The resonator (124) ensures impedance matching between the RF power generator (122) and the plasma load in the chamber (102), taking transmission line effects into account—standard practice in this technical field.

A gas distribution unit (118) interfaces with a gas/precursor source (120) through an aperture in the window (110), which is crucial for maintaining the vacuum integrity of the chamber (102). The gas/precursor source (120) may include separate delivery systems for gases and precursors, such as a gasbox for gases and vaporized liquid or solid precursor delivery systems. Depending on the embodiment, the gas distribution unit (118) can function as an injector or a showerhead.

In some embodiments, the window (110) itself integrates with the gas distribution unit (118) to act as a showerhead, ensuring a sealed environment while enabling lateral gas introduction into the chamber (102).

Inside the chamber (102), a chuck (114) supports a substrate (116). This chuck (114) could be an electrostatic chuck (ESC), a vacuum chuck, or another appropriate type depending on the specific application.

The chamber (102) is divided into an upper chamber (106) and a lower chamber (108) by a GIF (130). The GIF (130), positioned parallel to the substrate (116), is made from conductive materials such as aluminum or silicon, with anodized aluminum used for increased resistance to erosion. The GIF (130) can be grounded through the chamber body (104) or other grounded structures within the chamber (102).

The upper chamber (106) operates as an ICP chamber, where plasma is ignited to generate electrons, ions, and neutrals. The GIF (130) selectively blocks ions while allowing neutrals to pass through its multiple openings.

FIG. 1B provides a top-view illustration of the GIF (130), highlighting an example of an opening (132). FIG. 1C further defines each opening by its diameter (d) and height (h). To effectively block ions while permitting neutral flow, the openings are designed with a small diameter and a high aspect ratio (h/d), with heights ranging from 0.1 mm to 10 mm and aspect ratios between 10 and 500.

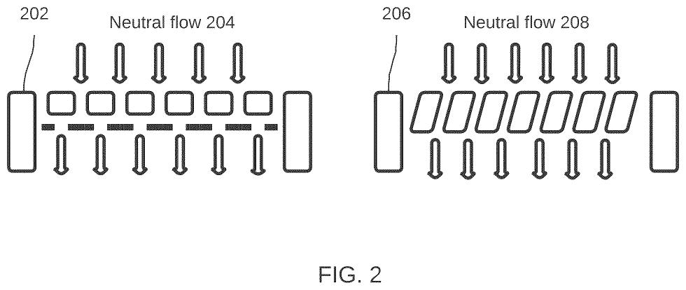

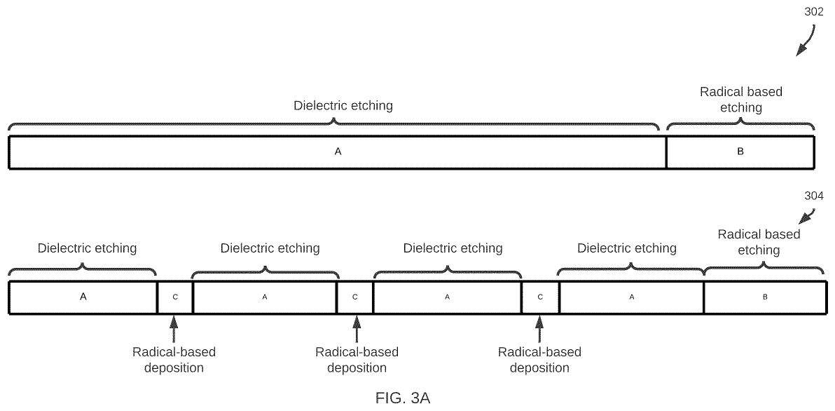

FIG. 2 illustrates two implementations of the GIF (130). In the first design (202), the conducting channels for neutrals in the GIF (130) consist of a series of vertical holes forming a first group, connected to horizontal conducting channels, which in turn links to a second group of vertical holes. The holes in the second group are deliberately misaligned with those in the first group, ensuring effective ion blockage while allowing neutral flow (204) to diffuse through the GIF (130).

The second design (206) features angled openings in the GIF (130) relative to its vertical axis. This configuration prevents ions from passing through the angled openings while allowing neutral flow (208) to diffuse through.

These designs are illustrative and not exhaustive. The openings in the GIF (130) can vary in shape, including square, rectangular, elliptical, hexagonal, and octagonal forms. Their sizes, depths, and distribution may be uniform or non-uniform, and the thickness of the GIF (130) is also variable. The invention covers various methods for ion obstruction, such as multiple horizontal conducting channels or angled openings.

Referring back to FIG. 1A, during operation, the upper chamber (106) functions as an ICP chamber. Once plasma is ignited, electrons move toward the GIF (130) and the chamber body (104). Since the GIF (130) is grounded without a blocking capacitor, the plasma sheath on its surface remains thin, minimizing ion penetration and enhancing the GIF's (130) durability and resistance to ion bombardment.

Conversely, the lower chamber (108) operates as a CCP chamber. In this configuration, the GIF (130) acts as the grounded electrode, while the chuck (114) serves as the powered electrode. In one setup, the chuck (114) is powered by RF power at a specified frequency from a bias unit (126), typically ranging from 100 kHz to 100 MHz, delivered through an unillustrated resonator. Alternatively, the bias unit (126) may supply RF power at multiple frequencies, including 100 kHz, 400 kHz, 1 MHz, 2 MHz, 13.56 MHz, and 60 MHz. This bias creates a voltage difference between the chuck (114) and the GIF (130), initiating plasma between these two electrodes. While plasma density in a CCP reactor is generally lower than in an ICP reactor, increasing the RF power frequency from the bias unit (126) boosts plasma density in the lower chamber (108).

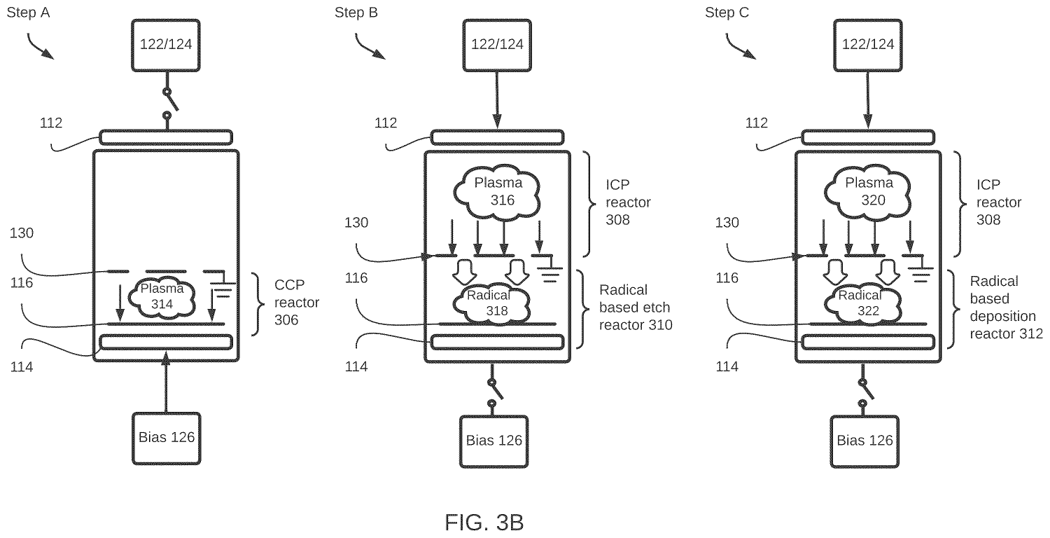

FIG. 3A illustrates two exemplary process sequences utilizing the process system (100). In the first scenario (302), the process begins with a dielectric etching step (A), targeting a specific dielectric material layer, followed by a radical-based HSE step (B). For an HAR etching, etching stop layers are typically applied. The etch stop layers are placed beneath an inter-metal dielectric (IMD) layer formed by a low-k film. Conventionally, after dielectric material etching of the IMD layer etching in a CCP reactor, a wet etching step is used to remove the etching stop layers due to high selectivity requirements. This invention enables both the dielectric etching of the low-k layer and the radical-based HSE of the etch stop layers to be completed within a single process chamber, reducing cycle time and improving performance. The gases used to remove the etching stop layers depend on the layer's material, with halogen-containing gas radicals being a common choice.

In the second scenario (304), the dielectric etching step is segmented into several sub-steps, with a radical-based deposition step (C) inserted between them. This deposition step (C) is critical for protecting the sidewalls of HAR structures from lateral etching, which can cause bowing of the structure. As is well known in the art, radical-based deposition can deposit high-quality films with excellent step coverage, such as silicon nitride, to effectively protect sidewalls. After the etching-deposition cycle, a radical-based HSE step is performed to remove the etching stop layers.

FIG. 3B illustrates the operating modes of the process system (100) for steps A, B, and C:
Step A (Dielectric Material Etching): The bias unit (126) supplies RF power to the chuck (114), converting the lower chamber (108) into a CCP reactor (306). In this configuration, the chuck (114) acts as the anode and the GIF (130) as the cathode. Carbon-fluorine compounds are exemplarily introduced, creating plasma (314) between the GIF (130) and the substrate (116). A typical dielectric material etching process involves carbon/fluorine polymer layer deposition followed by a sputtering step, using argon ions accelerated toward the substrate (116) to perform etching.
Step B (HSE): Process gases are introduced from the gas source through the gas distribution unit (118). The plasma source (112) generates plasma (310) in the upper chamber (106), functioning as an ICP reactor (308). The GIF (130) blocks ions while allowing neutral/radicals (318) to diffuse and etch the substrate surface (116). The lower chamber (108) operates as a radical-based etch reactor (310), or simply called as radical reactor, with the bias unit (126) deactivated to prevent ion generation.
Step C (Radical-based deposition): Gases and precursors are supplied similarly, with the addition of a vaporized liquid precursor delivery system, if needed. Plasma (320) is generated in the upper chamber (106), allowing radicals to diffuse into the lower chamber (108). A material layer is deposited on the substrate surface (116), with the lower chamber (108) functioning as a radical-based deposition reactor (312). The bias unit (126) remains deactivated to avoid ion generation.

Overall, the process system, as shown in FIG. 1A, enables both dielectric material etching in the CCP reactor and radical-based HSE in the lower chamber (108). The separation of the upper and lower chambers by the GIF (130) allows precise regulation of ion and neutral flow, optimizing conditions for each process step. This precise control over the etching process results in higher-quality and more reliable semiconductor devices.

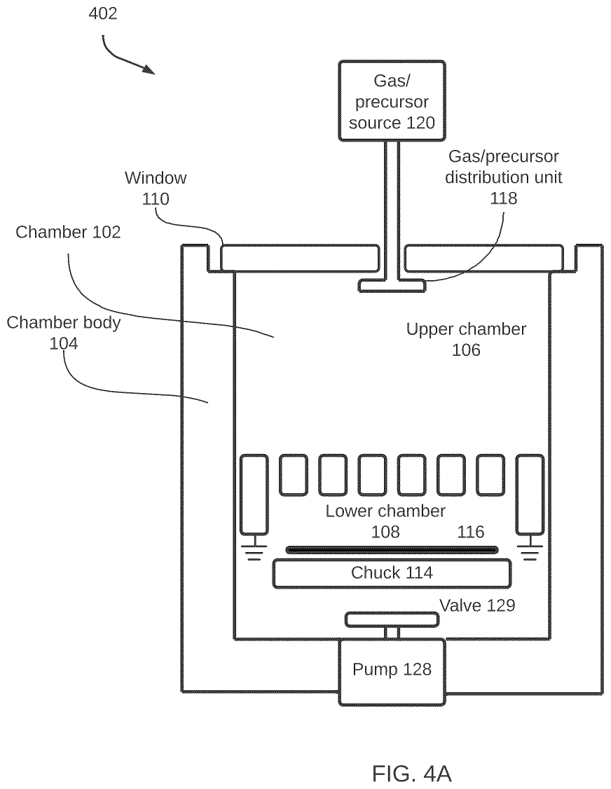

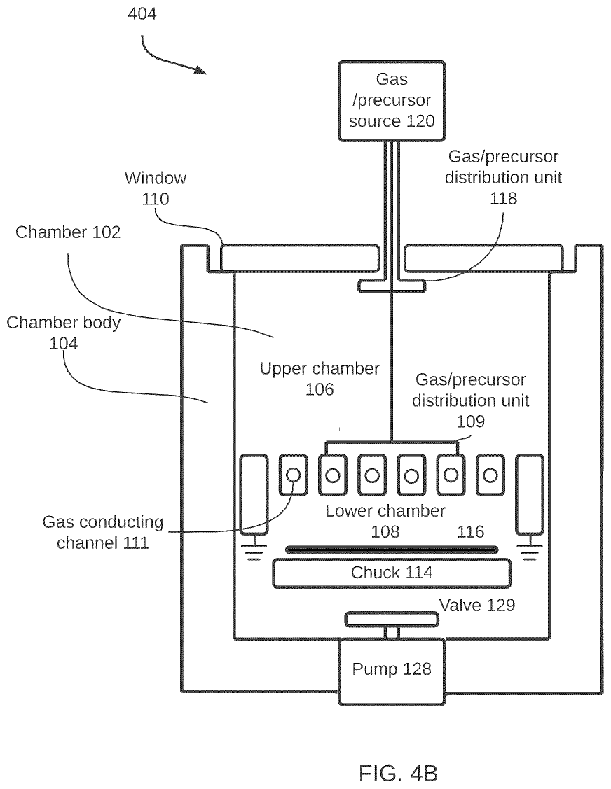

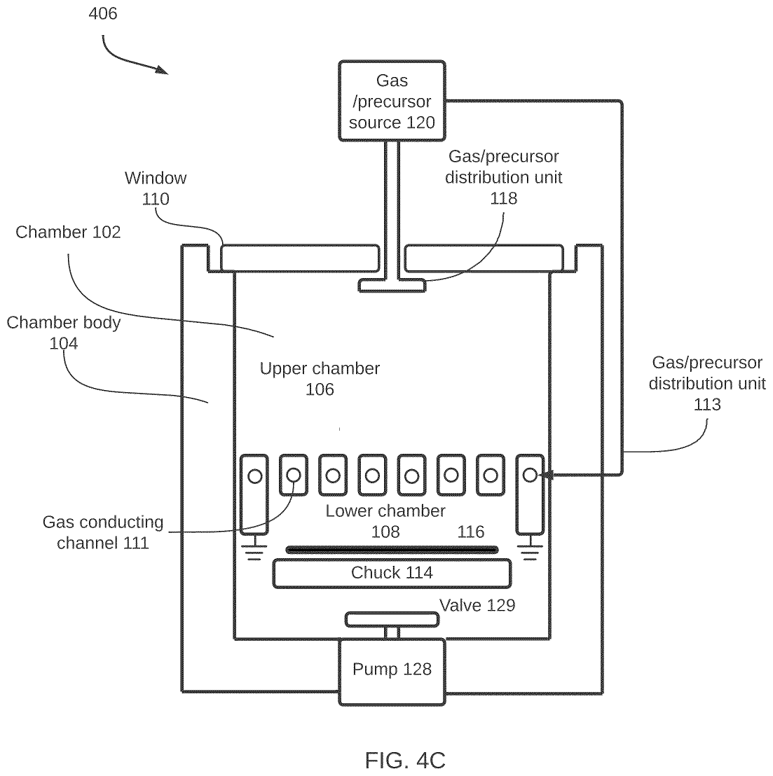

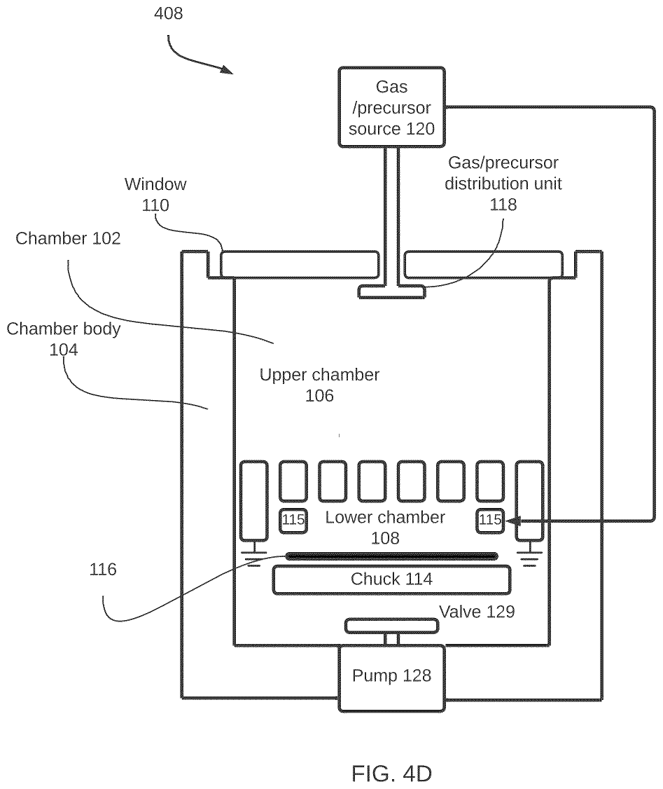

FIGS. 4A-D explore various approaches for introducing gases into the lower chamber (108). In one configuration, gas flows from the gas/precursor source (120) into the upper chamber (106) via the gas/precursor distribution unit (118), then diffuses through the GIF (130) into the lower chamber (108). Another setup utilizes the GIF (130) as a showerhead, with an internal gas distribution unit (109)—a version of the second gas/precursor distribution unit—directing gas straight from the gas/precursor source (120) into the lower chamber (108). An alternative configuration features another version of the second gas/precursor distribution unit (113) located at the side of the GIF (130), equipped with multiple ports to evenly distribute gas from the gas source (120). Finally, a method is shown where gas is injected directly into the lower chamber (108) through yet another version of the second gas distribution unit (115), located below the GIF (130). These examples represent potential configurations, but a wide range of other variations are also possible within the inventive scope.

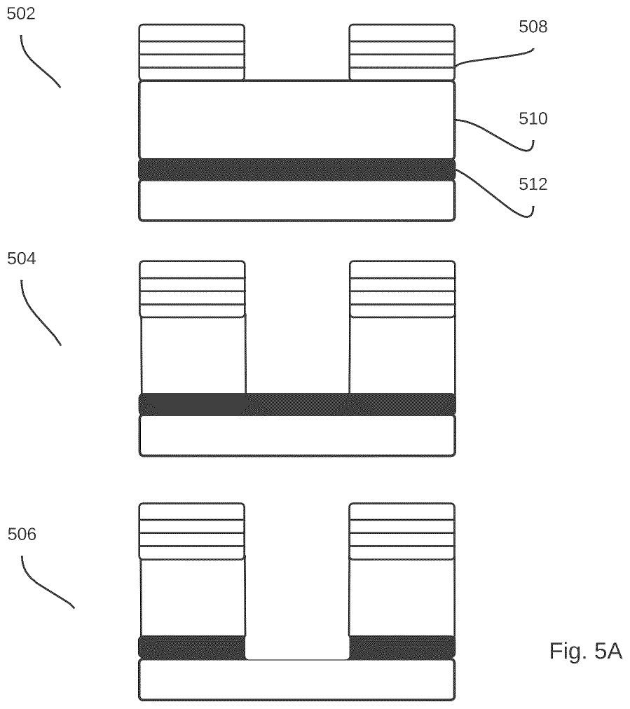

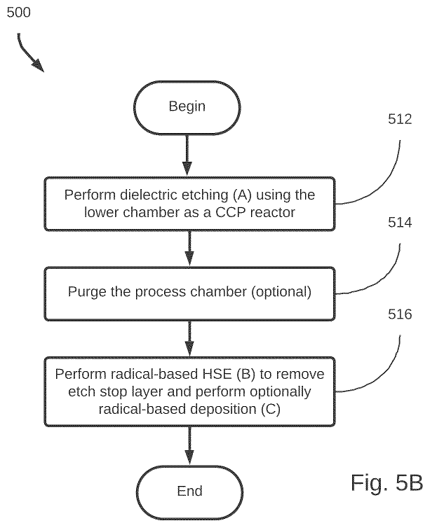

FIGS. 5A and 5B illustrate an example of using the process system (100) for a dielectric etching process. FIG. 5A shows a schematic process flow with cross-sectional changes to the structure. The incoming substrate (502) includes a mask layer (508) and a targeted layer (510) intended for etching, with etch stop layers (512) beneath. The mask layer (508) may comprise a photoresist or a hard mask, such as carbon, and can be augmented with performance-enhancing layers. The targeted layer and etch stop layers are placed beneath the inter-metal dielectric (IMD) layer, which may be a low-k film. The etch stop layers may further comprise a copper diffusion barrier layer and multiple layers for stopping the etching process.

FIG. 5B presents a process flowchart for the dielectric material etching process. It begins with the introduction of process gases into the lower chamber (108), which operates as a CCP reactor (306) to etch the dielectric material (A) in step 512. An optional purging step (514) follows, clearing the chamber before process gases are supplied to the upper chamber (106), now functioning as an ICP reactor. In step 516, neutrals, including radicals from the upper chamber (106), diffuse into the lower chamber (108) to perform radical-based HSE (B), specifically targeting the etch stop layers (512). In some implementations, during step 514, the lower chamber (108) can also serve as a radical deposition chamber, depositing material to protect the sidewalls of the structure being etched (C), ensuring optimal etching results.

1. A process chamber configured to perform dielectric material etching and radical-based HSE processes, comprising:
an upper chamber and a lower chamber separated by a GIF;
a plasma source coupled to an RF power generator configured to generate an inductively coupled plasma in the upper chamber;
a bias unit operatively connected to a chuck in the lower chamber;
a first gas/precursor distribution unit configured to deliver a gas or a precursor to the upper chamber;
a second gas/precursor distribution unit to deliver a gas or a precursor to the lower chamber; and
a system controller configured to:
operate the process chamber in a first mode for dielectric material etching, wherein the chuck and the GIF form a capacitively coupled plasma in the lower chamber; and
operate the process chamber in a second mode for a radical-based HSE, wherein the plasma source generates an inductively coupled plasma in the upper chamber, wherein the GIF blocks ions in the plasma from entering the lower chamber, while allowing radicals in the plasma to diffuse through openings in the GIF to etch a substrate.

2. The chamber of claim 1, wherein the system controller is further configured to a third mode for a radical-based deposition, wherein the plasma source generates an inductively coupled plasma in the upper chamber, wherein the GIF blocks ions from the plasma from entering the lower chamber while allowing radicals in the plasma to diffuse through the openings in the GIF to deposit a layer on the substrate surface.

3. The chamber of claim 2, wherein the radical-based deposition is configured to prevent lateral etching of a structure while the system controller is operating the chamber in the first mode.

4. The chamber of claim 1, wherein the system controller is further configured to conduct a purge step between a transition from the first to the second modes or between a transition from the second to the first modes.

5. The chamber of claim 1, wherein the radical-based HSE is performed after the dielectric material etching to remove etch stop layers.

6. The chamber of claim 1, wherein the openings in the GIF are dimensioned and arranged to minimize ion leakage through the openings.

7. The chamber of claim 1, wherein the openings in the GIF are angled relative to the vertical direction of the substrate surface.

8. The chamber of claim 1, wherein the GIF comprises a first set of openings connected by horizontal conducting channels to a second set of openings, wherein the second set of openings are misaligned with the first set.

9. The chamber of claim 1, wherein the bias unit is configured to supply RF power across one or more frequencies.

10. The chamber of claim 1, wherein the second gas/precursor distribution unit further utilizes the GIF as a showerhead.

11. A method for processing a substrate, comprising:
providing a process chamber comprising an upper chamber and a lower chamber separated by a GIF, the process chamber further comprising a plasma source configured to generate an inductively coupled plasma in the upper chamber, a bias unit operatively connected to a chuck in the lower chamber, a first and a second gas distribution units, and a system controller; and
performing a process by the system controller, comprising:
introducing a first set of process gases into the lower chamber and operating the bias unit to supply RF power to the chuck, thereby igniting a capacitively coupled plasma in the lower chamber and operating it into a CCP reactor defined by the chuck as an anode and the GIF as the cathode to etch a substrate; and
introducing a second set of process gases into the upper chamber and operating the plasma source to generate an inductively coupled plasma in the upper chamber while ceasing to supply RF power to the bias unit, such that ions from the plasma are blocked by the GIF and only neutrals from the plasma are allowed to pass through the GIF and conduct a radical-based HSE in the lower chamber.

12. The method of claim 11, wherein the radical-based HSE is performed after completing the etching in the CCP reactor.

13. The method of claim 12, wherein the etching process in the CCP reactor forms a HAR structure comprising a stack of multiple materials, and the radical-based HSE is employed to remove etch stop layers.

14. A method of etching dielectric material layers on a substrate, comprising:
providing a process chamber comprising an upper chamber and a lower chamber separated by a GIF, the process chamber further comprising a plasma source configured to generate a plasma in the upper chamber, a bias unit operatively connected to a chuck in the lower chamber, a first and a second gas distribution units, and a system controller;
introducing by the system controller a first set of process gases or precursors into the lower chamber through the second gas/precursor distribution unit and operating the bias unit to supply RF power to the chuck, thereby igniting a plasma in the lower chamber and converting it into a CCP reactor defined by the chuck as an anode and the GIF as the cathode to etch the dielectric material layers; and
introducing by the system controller a second set of process gases or precursors into the upper chamber through the first gas/precursor distribution unit and operating the plasma source to generate an inductively coupled plasma in the upper chamber while ceasing to supply RF power to the bias unit, such that ions from the plasma are blocked by the GIF and only neutrals from the plasma are allowed to pass through the GIF and conduct a radical-based deposition process to deposit a layer on the substrate.

15. The method of claim 14, further including removing the deposited layer at the bottom of a structure while maintaining the layer on sidewalls of structures formed on the substrate.

16. The method of claim 14, wherein the dielectric material layers comprise low-k materials positioned between two interconnect layers.

17. The method of claim 14, wherein the etching stop layers comprise a copper diffusion barrier layer.

18. The method of claim 14, wherein the first set of process gases further comprise halogen-containing gases.

19. The method of claim 14, wherein the second gas/precursor distribution system further utilizes the GIF as a showerhead.

20. The method of claim 14, wherein the second gas/precursor distribution system further comprises injection points positioned below or along an edge of the GIF.
